(19) United States
(12) Patent Application Publication
(10) Pub. No.: US 2026/0333990 A1
(43) Pub. Date: Oct. 22, 2026

(54) CONDUCTIVE SUBSTRATE

(71) Applicant: Panasonic Intellectual Property Management Co., Ltd., Kadoma-shi, Osaka (JP)

(72) Inventors: Takeshi Haritani, Hyogo Ken (JP); Shoji Fujii, Osaka Fu (JP)

(73) Assignee: Panasonic Intellectual Property Management Co., Ltd., Kadoma-shi, Osaka (JP)

(21) Appl. No.: 19/119,504

(22) PCT Filed: Oct. 18, 2023
(86) PCT No.: PCT/JP2023/037659

§ 371 Date: Apr. 9, 2025

(30) Foreign Application Priority Data
Nov. 14, 2022 (JP) 2022-181707

(51) Int. Cl. H10K 30/81; G02F 1/155; H10K 30/50; H10K 50/813

(52) U.S. Cl. CPC H10K 30/81; G02F 1/155; H10K 50/813; G02F 2001/1555; G02F 2201/122; H10K 30/50

(57) ABSTRACT

A conductive substrate includes a substrate including a flat surface and a first electrode. The first electrode includes a plurality of conductive lines each made of a conductive metal embedded in part of the substrate that is near the flat surface. The surface of each conductive line is substantially flush with the flat surface of the substrate.

### TECHNICAL FIELD

The present disclosure relates to a conductive substrate.

### BACKGROUND ART

A traditional conductive substrate used for a solar cell, an organic light emitting diode (OLED), a dimming device, and the like is known. For example, a conductive substrate of Patent Document 1 used for a solar cell is known.

Patent Document 1 discloses an organic thin-film solar cell using a transparent resin film. For example, the organic thin-film solar cell shown in FIG. 7 of Patent Document 1 includes a transparent substrate made of a transparent resin film, a mesh electrode formed on the transparent substrate, a transparent electrode formed on the transparent substrate, a hole extraction layer formed on the transparent electrode, a photoelectric conversion layer formed on the hole extraction layer, an electron extraction layer formed on the photoelectric conversion layer, and a counter electrode formed on the electron extraction layer.

### CITATION LIST

### Patent Document

Patent Document 1: Japanese Unexamined Patent Publication No. 2010-157681.

### SUMMARY OF THE INVENTION

### Technical Problem

In the above organic thin-film solar cell, the mesh electrode protrudes from the upper surface of the transparent substrate toward where the counter electrode is located. For this configuration, if the transparent electrode, the hole extraction layer, the photoelectric conversion layer, and the electron extraction layer are thin, each layer might be divided in the longitudinal direction of the raised shape from the corner portion of each mesh electrode. In this case, the function of each layer is impaired. Further, if each layer is divided, all the layers from the transparent electrode surrounding each mesh electrode to the counter electrode can slip off toward the transparent substrate, and the distance between the counter electrode formed on the electron extraction layer and the corner portion of each mesh electrode might be shortened. In this case, the counter electrode and the corner portion of each mesh electrode can come into contact with each other, which might cause an electrical short circuit.

In this manner, the configuration of Patent Document 1 might impair the original function of the device for which the conductive substrate is used.

In view of the foregoing, an object of the present disclosure is to avoid impairing the original function of a device for which the conductive substrate is used.

### Solution to the Problem

In order to achieve the above object, one embodiment of the present disclosure is directed to a conductive substrate used to attach a functional layer and a second electrode, including: a substrate including a flat surface; and a first electrode formed on the substrate. The first electrode includes a plurality of conductive lines each made of a conductive metal embedded in part of the substrate that is near the flat surface. The flat surface of the substrate is configured so that the functional layer and the second electrode can be arranged on the flat surface. The surface of each of the plurality of conductive lines is substantially flush with the flat surface.

### Advantages of the Invention

According to the present disclosure, it is possible to avoid impairing the original function of the device for which the conductive substrate is used.

### BRIEF DESCRIPTION OF THE DRAWINGS

FIG. 1 is a partially enlarged plan view of a conductive member including a conductive substrate according to an embodiment of the present disclosure, where part of a conductor pattern is schematically enlarged.

FIG. 2 is a cross-sectional view taken along line II-II of FIG. 1.

FIG. 3 is a partially enlarged cross-sectional view of the area III of FIG. 2, and schematically shows carrier paths that appear when the conductive member including the conductive substrate is used for a solar cell.

FIG. 4 is a schematically enlarged diagram showing that the flat surface of the substrate and the surface of the conductive line are flush with each other.

FIG. 5 corresponds to FIG. 3 and schematically shows carrier paths that appear when the conductive member including the conductive substrate is used for an OLED according to a first variation of the embodiment.

FIG. 6 corresponds to FIG. 3 and schematically shows carrier paths that appear when the conductive member including the conductive substrate is used for a dimming device according to a second variation of the embodiment.

FIG. 7 is a schematically enlarged diagram showing that the surface of the conductive line is recessed downward below the flat surface of the substrate according to a third variation of the embodiment.

FIG. 8 corresponds to FIG. 1 and is a schematically enlarged view of part of a conductor pattern different from the conductor pattern of FIG. 1 according to a fourth variation of the embodiment.

FIG. 9 corresponds to FIG. 3 and schematically shows a cross-sectional structure of a conductive member that includes a conductive substrate provided with a first electrode and a conductive substrate provided with a second electrode according to a fifth variation of the embodiment.

### DESCRIPTION OF EMBODIMENTS

Embodiments of the present disclosure will now be described in detail with reference to the drawings. Note that the following description of the embodiment is merely an example in nature, and is not intended to limit the scope, applications, or use of the present disclosure.

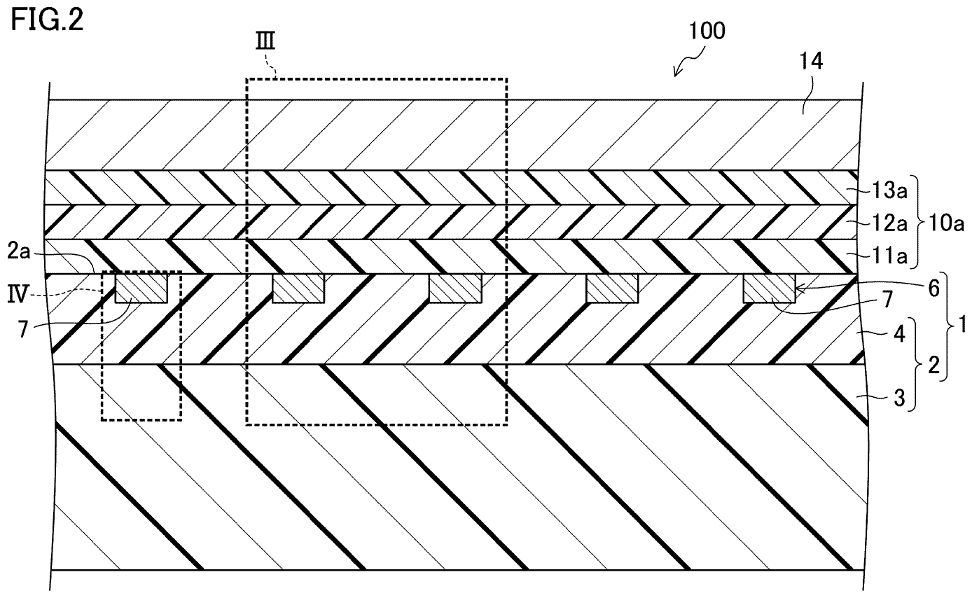

An embodiment of the present disclosure is directed to a conductive substrate 1 that is used to attach a functional layer 10a and a second electrode 14 (see FIG. 2). As shown in FIG. 2, the conductive substrate 1 includes a substrate 2 and a first electrode 6. The conductive substrate 1 is disposed below the functional layer 10a (or disposed near the lower surface of a hole transport layer Ila described later).

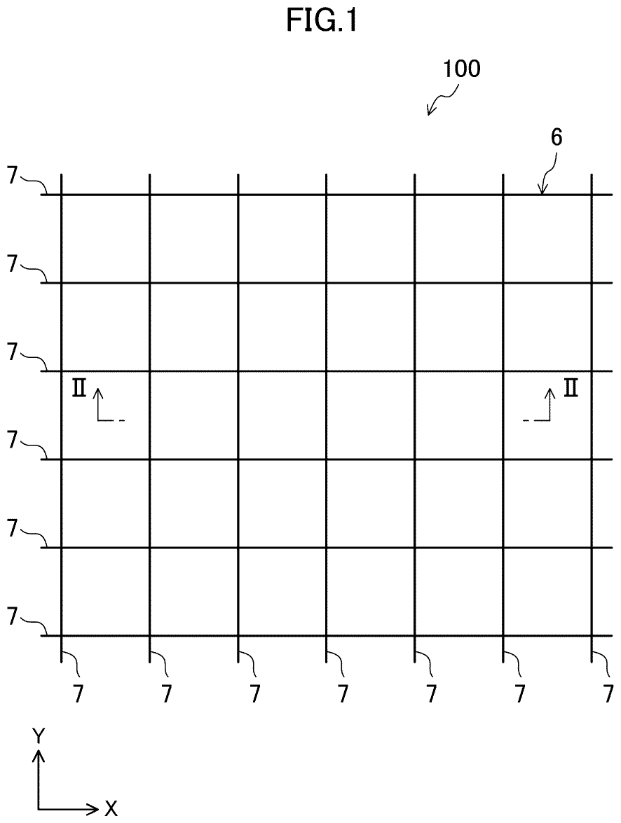

FIG. 1 schematically shows part of a conductive member 100. As shown in FIG. 2, the conductive member 100 includes the conductive substrate 1, the functional layer 10a, and the second electrode 14. The conductive member 100 can be used for a solar cell, an organic light emitting diode (OLED), a dimming device, and the like. This embodiment is an example embodiment in which the conductive member 100 is used for a solar cell.

Here, the direction from left to right on the sheet of FIG. 1 is defined as the “X direction,” and the direction from bottom to top on the sheet of FIG. 1 is defined as the “Y direction.”

In the following description, in the thickness direction of the conductive member 100 shown in FIG. 2, the side on which the second electrode 14 described later is located is defined as the “upper side” of the conductive member 100, and the opposite side (or the side on which a film base 3 described later is located) is defined as the “lower side” of the conductive member 100, whereby the positional relationship among the elements of the conductive member 100 will be defined. Note that this positional relationship is irrelevant to the actual directions for a device in which the conductive member 100 is incorporated.

### Substrate

As shown in FIG. 2, the substrate 2 has transparency and light-transmissive properties. The substrate 2 has a flat surface 2a. In this embodiment, the flat surface 2a corresponds to an upper surface of a resin layer 4 described later.

The substrate 2 includes a film base 3. The film base 3 is made of a resin material with flexibility, transparency, and light-transmissive properties. The film base 3 has a thickness of 20 μm to 200 μm, for example.

Examples of the resin material include resin materials such as polyethylene terephthalate (PET), polycarbonate, a cycloolefin polymer (COP), and a cycloolefin copolymer (COC).

The substrate 2 includes the resin layer 4. The resin layer 4 is made of a resin material having insulating properties and light-transmissive properties. The resin layer 4 has a thickness of 1 μm to 10 μm, for example.

The resin layer 4 is stacked above the film base 3. The upper surface of the resin layer 4 (i.e., the flat surface 2a) is substantially flat except for a plurality of recesses 5 described later.

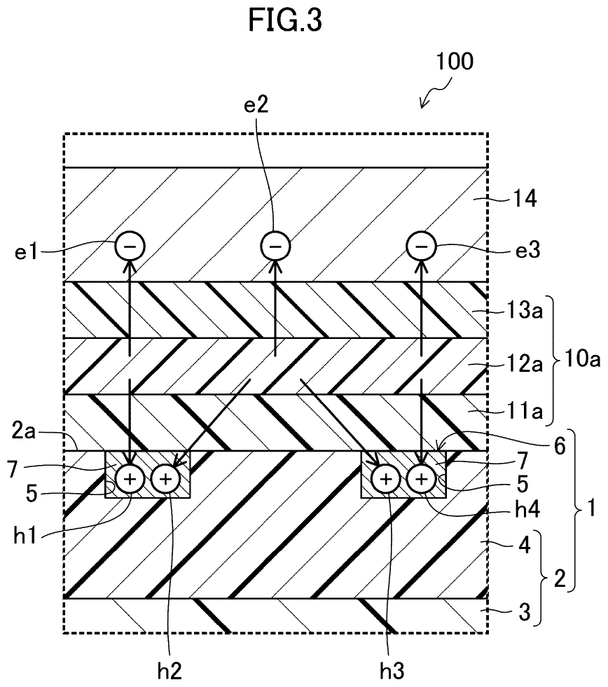

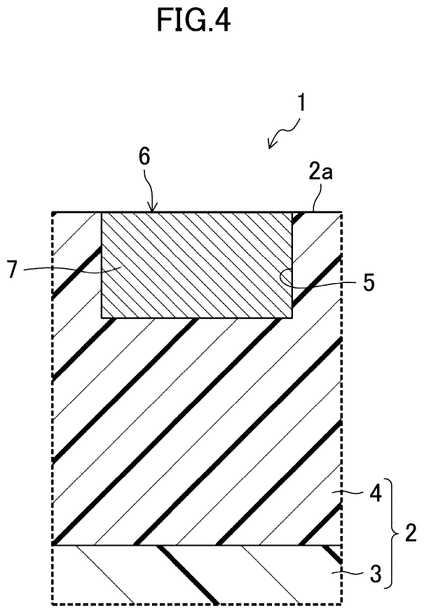

As shown in FIGS. 3 and 4, the resin layer 4 has the plurality of recesses 5, each having a bottom and recessed downward from the upper surface of the resin layer 4. The plurality of recesses 5 linearly extends on the upper surface of the resin layer 4 (the flat surface 2a) to form a predetermined pattern described later. The plurality of recesses 5 are formed on the upper surface of the resin layer 4 by hot embossing, an etching method by photolithography, laser machining, or the like.

### First Electrode

As shown in FIGS. 1 and 2, the first electrode 6 is configured as a conductor pattern formed near the flat surface 2a of the substrate 2 (or near the upper surface of the resin layer 4). The conductor pattern is formed by a plurality of conductive lines 7. The plurality of conductive lines 7 are disposed in part of the substrate 2 that is near the flat surface 2a.

The conductor pattern is arranged on the flat surface 2a of the substrate 2 to form a predetermined pattern. FIG. 1 shows a mesh pattern as an example of the predetermined pattern in which the plurality of conductive lines 7 are arranged in a mesh shape.

The mesh pattern is configured so that the plurality of conductive lines 7 extending in the X direction intersect with the plurality of conductive lines 7 extending in the Y direction. The plurality of conductive lines 7 extending in the X direction are arranged at equal intervals. The plurality of conductive lines 7 extending in the Y direction are arranged at equal intervals. In this embodiment, two conductive lines 7, 7 extending in the X direction and adjacent to each other and two conductive lines 7, 7 extending in the Y direction and adjacent to each other form one single cell with a square shape.

Each conductive line 7 is thin. Each conductive line 7 has a width of 10 μm or less, for example.

As shown in FIGS. 2 to 4, each conductive line 7 is made of a conductive metal embedded in the recess 5 of the substrate 2. Suitable examples of this conductive metal include copper (Cu), silver (Ag), gold (Au), aluminum (Al), nickel (Ni), and an alloy containing at least one of these metals.

The embodiment of the present disclosure is characterized in that the surface of each conductive line 7 is substantially flush with the flat surface 2a of the substrate 2 while being exposed from the flat surface 2a of the substrate 2. As shown in FIG. 4, in this embodiment, the flat surface 2a of the substrate 2 is completely flush with the surface of each conductive lines 7. In FIG. 4, the hole transport layer 11a is not shown for convenience of illustration.

### Functional Layer

As shown in FIGS. 2 and 3, the functional layer 10a includes three layers. Specifically, the functional layer 10a includes the hole transport layer 11a, a charge generation layer 12a, and an electron transport layer 13a. The hole transport layer 11a, the charge generation layer 12a, and the electron transport layer 13a are stacked in this order on the flat surface 2a of the substrate 2 (or the upper surface of the resin layer 4). The functional layer 10a has a thickness of 3.0 μm or less. Preferably, the functional layer 10a has a thickness of 1.0 μm or less.

The charge generation layer 12a has an electron-donating function. Specifically, the charge generation layer 12a causes charge separation using a pn-junction formed in the charge generation layer 12a.

The charge generation layer 12a contains an electron-donating material. The electron-donating material is not particularly limited as long as it functions as an electron donor. Preferably, the electron-donating material is a material that can form a film by a wet coating method. In particular, a suitable example of the electron-donating material is an electron-donating conductive polymer material.

Examples of the electron-donating conductive polymer material include polyphenylene, polyphenylene vinylene, polysilane, polythiophene, polycarbazole, polyvinylcarbazole, porphyrin, polyacetylene, polypyrrole, polyaniline, polyfluorene, polyvinylpyrene, polyvinylanthracene, derivatives thereof, copolymers thereof, a phthalocyanine-containing polymer, a carbazole-containing polymer, and an organometallic polymer.

More preferably, examples of the electron-donating conductive polymer material include a thiophene-fluorene copolymer, polyalkylthiophene, a phenyleneethynylene-phenylenevinylene copolymer, a phenyleneethynylene-thiophene copolymer, a phenyleneethynylene-fluorene copolymer, a fluorene-phenylenevinylene copolymer, and a thiophene-phenylenevinylene copolymer.

The hole transport layer Ila has a function of transporting holes generated by the charge generation layer 12a toward each conductive line 7. The hole transport layer 11a enhances the efficiency of transportation of holes generated by the charge generation layer 12a. As a result, the efficiency of photoelectric conversion in the conductive member 100 used for a solar cell is improved.

Suitable examples of the material of the hole transport layer Ila include doped conductive organic compounds such as polyaniline, polyphenylene vinylene, polythiophene, polypyrrole, polyparaphenylene, polyacetylene, and triphenyldiamine (TPD); and organic materials that form a charge transfer complex consisting of an electron-donating compound such as tetrathiofulvalene or tetramethylphenylenediamine and an electron-accepting compound such as tetracyanoquinodimethane or tetracyanoethylene.

The hole transport layer 11a may be a thin film made of a metal material such as Au, In, Ag, or Pd. The thin film may be made of one single metal material such as Au, In, Ag, or Pd, or may be made of any combination of those metal materials and the above organic materials.

The electron transport layer 13a has a function of transporting electrons generated by the charge generation layer 12a toward the second electrode 14 described later. The electron transport layer 13a enhances the efficiency of transportation of electrons generated by the charge generation layer 12a. As a result, the efficiency of photoelectric conversion in the conductive member 100 used for a solar cell is improved.

Suitable examples of the material of the electron transport layer 13a include doped conductive organic compounds such as polyaniline, polyphenylene vinylene, polythiophene, polypyrrole, polyparaphenylene, polyacetylene, and triphenyldiamine (TPD); and organic materials that form a charge transfer complex consisting of an electron-donating compound such as tetrathiofulvalene or tetramethylphenylenediamine and an electron-accepting compound such as tetracyanoquinodimethane or tetracyanoethylene.

The material of the electron transport layer 13a may be a metal-doped layer with an alkali metal or an alkaline earth metal. Examples of the metal-doped layer include bathocuproine (BCP) or bathophenanthoron (Bphen), Li, Cs, Ba, Sr, and the like.

### Second Electrode

As shown in FIGS. 2 and 3, the second electrode 14 is stacked on the upper surface of the functional layer 10a (or the upper surface of the electron transport layer 13a). That is, the second electrode 14 faces the first electrode 6 with the functional layer 10a sandwiched therebetween in the thickness direction of the substrate 2.

In this embodiment, the second electrode 14 is made of a metal material having conductivity. Examples of the metal material may include Li, In, Al, Ca, Mg, Sm, Tb, Yb, Zr, LiF, Au, and Ag. The second electrode 14 may be made of a metal oxide such as indium tin oxide (ITO) or indium zinc oxide (IZO), or a transparent conductive polymer such as PEDOT/PSS.

In this embodiment, the second electrode 14 is a metal layer configured as a single layer (see FIGS. 2 and 3). The second electrode 14 is formed by a vacuum deposition method or a pattern deposition method using a metal mask, for example. The second electrode 14 may consists a plurality of stacked layers, each of which is made of a different metal material. The second electrode 14 may be a solid electrode formed on the entire upper surface of the charge generation layer 12a, or may be configured as thin metal wires formed in a predetermined pattern.

### Carrier Path

Carrier paths in a situation in which the conductive member 100 is used for a solar cell will be briefly described with reference to FIG. 3. The charge generation layer 12a generates carriers (electrons and holes) by light energy. The electrons (reference characters e1 to e3 in FIG. 3) generated by the charge generation layer 12a are transported toward the second electrode 14 via the electron transport layer 13a. The holes (reference characters h1 to h4 in FIG. 3) generated by the charge generation layer 12a are transported toward the first electrode 6 via the hole transport layer 11a.

### Advantages of Embodiment

The conductive substrate 1 of the embodiment of the present disclosure is configured so that the surface of each conductive line 7 is substantially flush with the flat surface 2a. That is, each conductive line 7 is configured not to protrude from the flat surface 2a of the substrate 2. According to this configuration, unlike the configuration of the known art, even if the functional layer 10a is relatively thin, the functional layer 10a cannot be divided in the thickness direction of the substrate 2 because each conductive line 7 does not have a raised shape. Further, since the functional layer 10a cannot be divided, each conductive line 7 cannot come into contact with the second electrode 14, and thus electrical short circuits do not occur. Thus, it is possible to avoid impairing the original function of the device (the solar cell in this embodiment) for which the conductive member 100 is used.

### First Variation of Embodiment

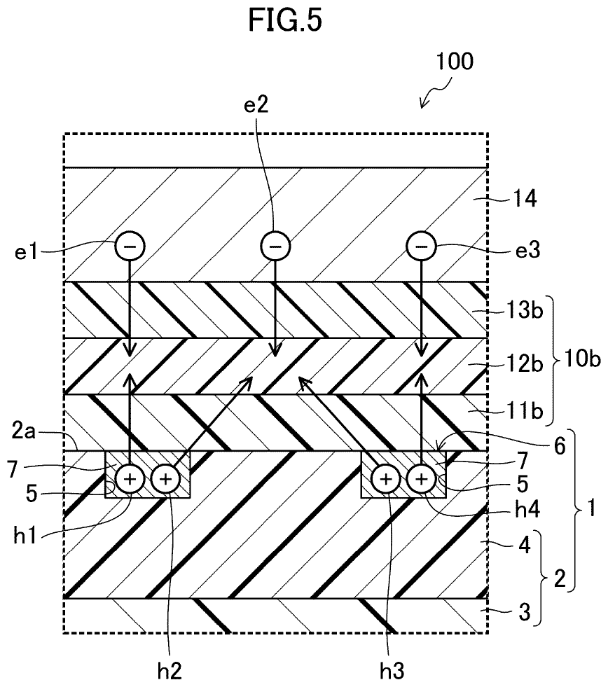

In the embodiment, the conductive member 100 is used for a solar cell, but the configuration is not limited thereto. For example, as shown in FIG. 5 as the first variation, the conductive member 100 may be used for an organic light emitting diode (OLED).

In the conductive member 100 of the first variation, the functional layer 10a is replaced with a functional layer 10b. As shown in FIG. 5, the functional layer 10b includes a hole transport layer 11b, a light emitting layer 12b, and an electron transport layer 13b. The hole transport layer 11b, the light emitting layer 12b, and the electron transport layer 13b are stacked in this order on the flat surface 2a of the substrate 2 (or the upper surface of a resin layer 4). The second electrode 14 is stacked above the electron transport layer 13b. The functional layer 10b has a thickness of 3.0 μm or less. Preferably, the functional layer 10b has a thickness of 1.0 μm or less.

In the first variation, the electron transport layer 13b has a function of transporting electrons (reference characters e1 to e3 in FIG. 5) supplied from the second electrode 14 toward the light emitting layer 12b. The hole transport layer 11b has a function of transporting holes (reference characters h1 to h4 in FIG. 5) supplied from the first electrode 6 toward the light emitting layer 12b. In the light emitting layer 12b, the electrons supplied from the electron transport layer 13b and the holes supplied from the hole transport layer 11b are recombined together. The energy generated by recombination of the electrons and the holes excites the molecules that form the light emitting layer 12b, and accordingly the light emitting layer 12b has a function of emitting light.

According to this variation, similarly to the embodiment, it is possible to avoid impairing the original function of the device (the OLED in this variation) for which the conductive member 100 is used.

### Second Variation of Embodiment

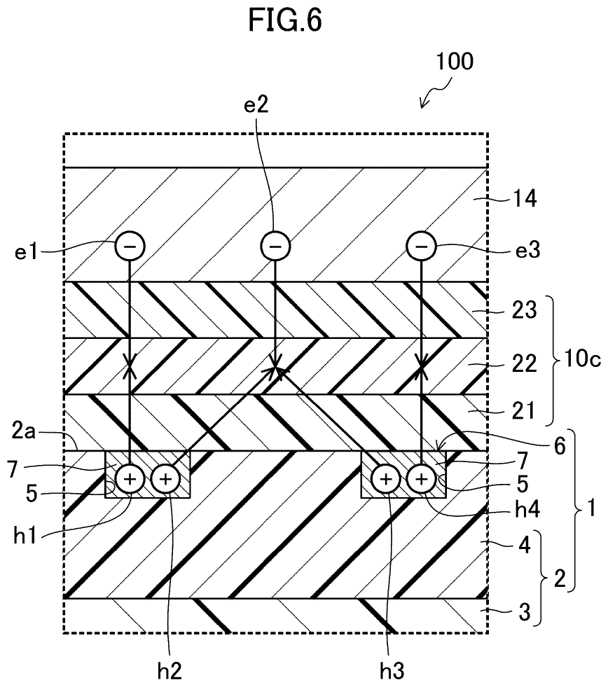

As shown in FIG. 6 as the second variation, the conductive member 100 may be used for a dimming device. In the conductive member 100 of the second variation, the functional layer 10a is replaced with a functional layer 10c. As shown in FIG. 6, in the second variation, the functional layer 10c includes an electrochromic layer 21, an electrolyte layer 22, and a counter electrode material layer 23. The electrochromic layer 21, the electrolyte layer 22, and the counter electrode material layer 23 are stacked in this order on the flat surface 2a of the substrate 2 (or the upper surface of a resin layer 4). The functional layer 10c has a thickness of 3.0 μm or less. Preferably, the functional layer 10c has a thickness of 1.0 μm or less.

In the second variation, the second electrode 14 is stacked above the counter electrode material layer 23. The second electrode 14 of the second variation is made of a material with transparency. Examples of the material of the second electrode 14 of the second variation include a metal oxide, a transparent conductive polymer, a transparent conductive ink, and a conductive metal.

Examples of the metal oxide include indium tin oxide (ITO) and indium zinc oxide (IZO). The metal oxide may be a metal oxide such as a zinc oxide, an indium oxide, an antimony-doped tin oxide, a fluorine-doped tin oxide, an aluminum-doped zinc oxide, a potassium-doped zinc oxide, a silicon-doped zinc oxide, a zinc oxide-tin oxide-based metal oxide, an indium oxide-tin oxide-based metal oxide, or a zinc oxide-indium oxide-magnesium oxide-based metal oxide; or a composite material of two or more of these metal oxides.

Examples of the transparent conductive polymer include poly-3, 4-ethylenedioxythiophene/polysulfonic acid (PEDOT/PSS). Examples of the transparent conductive ink include an ink that contains a binder with carbon nanotubes or silver nanofibers. Suitable examples of the conductive metal include copper, silver, gold, and an alloy containing at least one of these metals.

The electrochromic layer 21 has a function of coloring that is due to oxidation reaction induced by the holes supplied from the first electrode 6 (reference characters h1 to h4 in FIG. 6) and the electrons supplied from the second electrode 14 (reference characters e1 to e3 in FIG. 6). The counter electrode material layer 23 has a function of causing the reduction reaction against the oxidation reaction of the electrochromic layer 21 in order to stabilize the device. The electrolyte layer 22 has a function of blocking the electrons supplied from the second electrode 14 in order to prevent those electrons from escaping toward the second electrode 14 (or in the direction opposite to the first electrode 6).

According to this variation, similarly to the embodiment, it is possible to avoid impairing the original function of the device (the OLED in this variation) for which the conductive member 100 is used.

### Third Variation of Embodiment

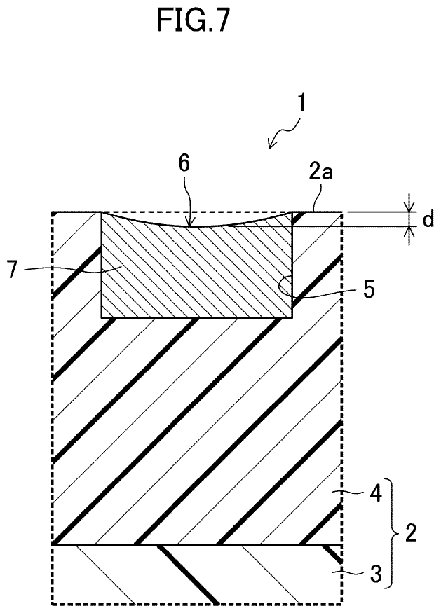

In the embodiment, the surface of the conductive line 7 is completely flush with the flat surface 2a of the substrate 2 (or the upper surface of the resin layer 4) (see FIG. 4), but the configuration is not limited thereto. That is, as shown in FIG. 7 as the third variation, the flat surface 2a of the substrate 2 does not have to be completely flush with the surface of conductive line 7. In FIG. 7, the hole transport layer 11a is not shown for convenience of illustration.

As shown in FIG. 7, the surface of the conductive line 7 may be recessed downward below the flat surface 2a of the substrate 2 (or recessed toward the bottom of the recess 5). Specifically, in the conductive member 100 of the third variation, the distance between the flat surface 2a of the substrate 2 and the deepest part of the surface of the conductive line 7 (or the dimension d in FIG. 7) is preferably set to −1.0 μm or more and 1.0 μm or less. More preferably, the dimension d is −0.1 μm or more and 0.0 μm or less.

According to the dimension d set as described above, the flat surface 2a of the substrate 2 can be regarded as being substantially flush with the surface of the conductive line 7 similarly to the embodiment. Thus, it is possible to avoid impairing the original function of the device for which the conductive member 100 of the third variation is used.

### Fourth Variation of Embodiment

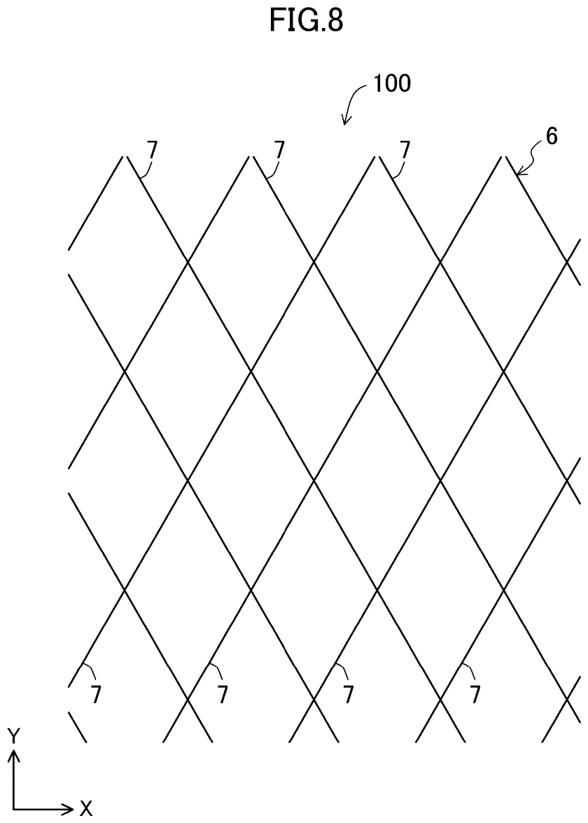

In the embodiment, in the first electrode 6, two conductive lines 7, 7 extending in the X direction and adjacent to each other and two conductive lines 7, 7 extending in the Y direction and adjacent to each other form one single cell with a square shape, but the configuration is not limited thereto. For example, as shown in FIG. 8 as the fourth variation, a plurality of conductive lines 7 may extend obliquely both in the X direction and in the Y direction so that four conductive lines 7 form one single cell with a diamond shape.

### Fifth Variation of Embodiment

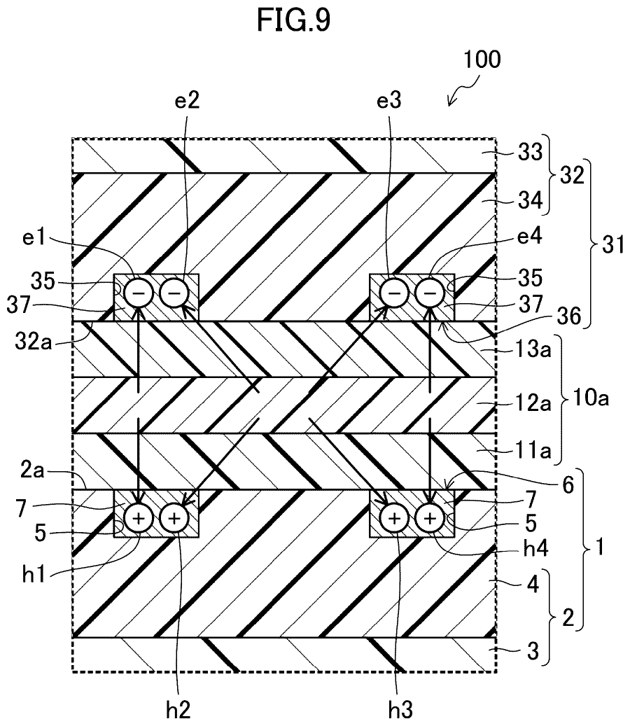

In the embodiment, the second electrode 14 is a metal layer configured as a single layer, but the configuration is not limited thereto. For example, instead of the second electrode 14 of the embodiment (see FIGS. 2 and 3), a conductive substrate 31 that includes a second electrode 36 may be provided as shown in FIG. 9 as the fifth variation. That is, the conductive member 100 of the fifth variation includes the conductive substrate I with the first electrode 6 and the conductive substrate 31 with the second electrode 36.

As shown in FIG. 9, the conductive substrate 31 includes a substrate 32 and the second electrode 36. The substrate 32 includes a film base 33 and a resin layer 34. The substrate 32 includes a flat surface 32a. The flat surface 32a corresponds to the lower surface of the resin layer 34. The resin layer 34 has a plurality of recesses 35.

The film base 33, the resin layer 34, and the plurality of recesses 35 have substantially the same structure as the film base 3, the resin layer 4, and the recess 5 of the embodiment, respectively. Thus, the detailed descriptions of the film base 33, the resin layer 34, and the recess 35 are omitted.

The second electrode 36 is configured as a conductor pattern formed by a plurality of conductive lines 37. The plurality of conductive lines 37 are disposed in part of the substrate 32 that is near the flat surface 32a. Each conductive line 37 is made of a conductive metal embedded in each recess 35 of the resin layer 34. The conductive metal of the conductive lines 37 is the same material as the conductive metal of the conductive lines 7 described in the embodiment. The surface of each conductive line 37 is substantially flush with the flat surface 32a of the substrate 32 while being exposed from the flat surface 32a.

Although not shown, the surface of the conductive line 37 may be recessed upward above the flat surface 32a (or recessed toward the bottom of the recess 35). In this case, the distance between the flat surface 32a and the deepest part of the surface of the conductive line 37 is −1.0 μm or more and 1.0 μm or less. More preferably, the distance is −0.1 μm or more and 0.0 μm or less.

As described above, in the fifth variation, the conductive substrate 31 that has the same structure as that of the conductive substrate 1 of the embodiment is provided above the functional layer 10a, thus providing the same advantage as that of the conductive substrate 1 of the embodiment. Thus, it is possible to avoid impairing the original function of the device for which the conductive member 100 of the fifth variation is used.

Although not shown, as another variation from the fifth variation, the conductive substrate 1 may be disposed above the functional layer 10a (or disposed near the upper surface of the electron transport layer 13a), and in contrast, the conductive substrate 31 may be disposed below the functional layer 10a (or disposed near the lower surface of the hole transport layer 11a).

### Other Embodiments

In the embodiment and the first and second variations, the conductive substrate 1 including the first electrode 6 is disposed below the functional layer 10a, and in contrast, the second electrode 14 is disposed above the functional layer 10a, but the configuration is not limited thereto. That is, although not shown, the conductive substrate 1 including the first electrode 6 (which is disposed above the electron transport layer 13a in the embodiment) may be disposed above the functional layer 10a, and in contrast, the second electrode 14 (which is disposed below the hole transport layer Ila in the embodiment) is disposed below the functional layer 10a.

### Industrial Applicability

The conductive substrate of the present disclosure is an industrially applicable conductive substrate that can be used for a device such as a solar cell, an OLED, or a dimming device.

### DESCRIPTION OF REFERENCE CHARACTERS

1, 31 Conductive Substrate
2, 32 Substrate
2a, 32a Flat Surface
3, 33 Film Base
4, 34 Resin Layer
5, 35 Recess
6 First Electrode
7, 37 Conductive Line
11a, 11b Hole Transport Layer
12a Charge Generation Layer
12b Light Emitting Layer
13a, 13b Electron Transport Layer
14, 36 Second Electrode
21 Electrochromic Layer
22 Electrolyte Layer
23 Counter Electrode Material Layer
100 Conductive Member

1. A conductive substrate used to attach a functional layer and a second electrode, comprising:
a substrate including a flat surface; and
a first electrode formed on the substrate,
wherein
the first electrode includes a plurality of conductive lines each made of a conductive metal embedded in part of the substrate that is near the flat surface,
the flat surface of the substrate is configured so that the functional layer and the second electrode can be arranged on the flat surface, and
a surface of each of the plurality of conductive lines is substantially flush with the flat surface.

2. The conductive substrate of claim 1, wherein
a distance between the flat surface of the substrate and a deepest part of the surface of each of the plurality of conductive lines is −1.0 μm or more and 0.0 μm or less.

3. A conductive substrate used to attach a functional layer and a first electrode, comprising:
a substrate including a flat surface; and
a second electrode formed on the substrate,
wherein
the second electrode includes a plurality of conductive lines each embedded in part of the substrate that is near the flat surface,
the flat surface of the substrate is configured so that the functional layer and the first electrode can be arranged on the flat surface, and
a surface of each of the plurality of conductive lines is substantially flush with the flat surface.

4. The conductive substrate of claim 3, wherein
a distance between the flat surface of the substrate and a deepest part of the surface of each of the plurality of conductive lines is −1.0 μm or more and 0.0 μm or less.
